(19) United States
(12) Patent Application Publication
(10) Pub. No.: US 2019/0221692 A1
(43) Pub. Date: Jul. 18, 2019

(54) Flexible Transparent-Semitransparent Hybrid Solar Window Membrane Module

(71) Applicant: Jiaxiong Wang, Danville, CA (US)

(72) Inventor: Jiaxiong Wang, Danville, CA (US)

(21) Appl. No.: 15/869,048

(22) Filed: Jan. 12, 2018

(51) Int. Cl. H01L 31/0392; H02S 20/22; H02S 30/00

(52) U.S. Cl. CPC H01L 31/03923; H02S 30/00; H02S 20/22

(57) ABSTRACT

The present invention provides a kind of flexible transparent-semitransparent hybrid solar window membrane modules. A module comprises a series of thin film transparent organic polymer solar cells, semitransparent perovskite solar cells, or hybrid of them. Both types of the solar cells are deposited onto a flexible transparent polymer membrane substrate. Those visibly transparent polymer solar cells contain a UV- and/or NIR-sensitive polymer layer to allow most visible light transmitted and semitransparent perovskite solar cells allows some portion of visible light transmitting. The resultant modules obtain benefits of transparency from the polymer cells and high efficiency from the perovskite ones. Both groups of the solar cells on one module have to be interconnected respectively. Two interconnection methods, the 3P scribing process and conductive strip connection, have been utilized. The modules are encapsulated with transparent materials to increase their lifetimes. These flexible solar window membrane modules can be adhered onto the glass windows of commercial buildings and family houses through electrostatic adsorption as solar energy sources. The modules used outdoors may be interconnected one another wired or wireless via resonant inductive coupling technology.

### FIELD OF THE INVENTION

The present invention relates to a flexible transparent-semitransparent hybrid solar window membrane module that comprises a number of transparent thin film polymer solar cells and/or semitransparent thin film perovskite solar cells. The resultant hybrid solar window membrane modules can be adhered onto the glass windows of buildings indoors or outdoors using electrostatic adsorption technology. A number of the modules can be interconnected to form solar arrays to convert solar energy into electricity. The outdoor modules may be installed with wireless charging-discharging devices to collect electricity generated by the solar window membrane modules. The present invention covers the fields of solar energy, membrane attachment and wireless charge/discharge technology.

### BACKGROUND OF THE RELATED ART

Photovoltaic (PV) technologies have been greatly developed in recent years due to concerns of exhaustion of fossil energy and global warm caused by this fossil energy. As a result, renewable energy has been developing to solve the problems. Because the sun is a sort of inexhaustible clean energy for the humanity, the solar cells have been greatly developed in recent years. The first generation of the solar cells, crystal silicon solar cells, has been developed for more than half a century. The second generation of the solar cells, thin film solar cells, has been developed in recent two decades for the main purpose of reducing costs of the solar cells. It is unexpected that the costs of crystal silicon solar cells are dramatically reduced in recent several years, which almost stops development of the thin film solar cells such as amorphous silicon solar cells, CdTe and CIGS solar cells.

Although crystal silicon solar cells currently dominate the solar cell market due to its high efficiency, long-life durability, inexpensiveness, and easy fabrication, they are still seldom to be seen around us. In general, the crystal silicon solar cells and other thin film solar cells are used on the roofs, but not frequently installed as components of building integrated photovoltaics (BIPV). It may be because most areas of a building, especially a skyscraper, probably are covered with glass windows. Some investigations revealed that the energy generated from the sun could provide more than 60% of electricity for a skyscraper if most of its windows were powered with solar modules. Therefore, it may give great contribution to BIPV if some solar modules can be applied to the glass windows of a building.

Unfortunately, it is very difficult to change a glass window into a solar panel because a window should be visibly transparent. The thin film solar cells may probably be applied onto a glass window to make it semitransparent if the absorb layers are thin enough to allow some portion of visible light to transmit the windows. However, the thin absorb layer means efficiency sacrifice of the solar cells. For example, a glass CIGS or a CdTe solar module may have a power conversion efficiency (PCE) of 14%. If someone attempts to make it less than 50% transparency, a thinner absorb layer may reduce its PCE down to 7% or lower. A fully transparent solar cell requires the visible light to be fully transmitted, and only the photons from ultraviolet (UV) and near-infrared (NIR) wavelengths in the solar spectrum to be absorbed. Some organic polymer solar cells (OPVs) may reach this target, but their PCEs are poor with common levels below 5%. This is because less photons can be used to excite electrons over a large gap between the valence band and the conduction band of the absorb layer if it absorbs only UV light. The resultant solar cell may have a large open circuit voltage (V_{oc}) but a small short circuit current density (J_{sc}). If the photoactive material mainly absorbs NIR photons to excite electrons, by contrast, the solar cell may have a small V_{oc} but a large J_{sc}, and may not be fully transparent because some visible light may still be absorbed owing to a small gap of the photoactive material.

Even if the second generation thin film solar modules, i.e., amorphous Si, CdTe and CIGS, are applied onto a semitransparent window, their manufactures are expensive due to complicated processes and expensive vacuum equipment. Recently, a new thin film PV device, perovskite solar cell, has appeared with the PCE as high as 22%. It is a kind of organic-inorganic halide solar cell, inexpensive and easy to prepare. The perovskite solar cells and OPVs belong to the third generation solar cells. The compositions of these perovskite solar cells can be modified to obtain better transparent characteristics than the second generation of thin film solar cells. They may be fabricated into semitransparent solar window modules with PCE large than 10%. They may also be incorporated with visibly transparent OPVs to form transparent-semitransparent hybrid solar window modules that take into account the benefits of both visibly transparency and solar cell PCEs.

Typical organic semiconductors used in OPVs usually comprise photoactive materials such as polyalkylthiophene (PAT): [6,6]-phenyl-C₆₁-butyric acid methyl ester (PCBM) blends to form a bulk-heterojunction (BHJ) device. However, due to their efficient photon harvesting in the visible wavelength region, the PAT:PCBM solar cells often have low visible transparency. For example, poly(3-hexylthiopnehe) (P3HT), was extensively investigated and used. However, the dominant absorption of P3HT is located in the yellow-green wavelength region (500-600 nm) where human eyes have the highest sensitivity. On the other hand, the state-of-the-art photoactive materials sensitive to UV and NIR photons were frequently reported in the last decade. For example, Yang Yang group reported to use selenium substituted thiophene polymer poly-{2,6′-4,8-di(5-ethylhexylthienyl)benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP, E_{g}=1.38 eV) as a photoactive layer that combined [6,6]-phenyl-C₇₁-butyric acid methyl ester (PC₇₁BM) to demonstrate 4.5% PCE for a visibly transparent OPV (Dou, L. et al, Adv. Mater., 2013, 25, 825-837). This photoactive material absorbs the photons in NIR region (600-900 nm) to make the devices highly transparent.

Some state-of-the-art donor polymers are those copolymers giving rise to two distinct absorption bands. While one of them is deep in the NIR region, the other one is typically located in the UV region to result in much weaker visible absorption. As a result, it is possible to make a photoactive layer thick enough to pursue high efficiency utilizing both NIR and UV photons, and meanwhile maintain high visible transparency. Until now, the achievement in high efficient visibly transparent organic polymer solar cells (VTOPVs) is limited by the low bandgap photoactive materials that not only generate high external quantum efficiency in the NIR and UV region, but also minimize photo-voltage loss.

On the other hand, the transparent conductor is another issue to determine the performance of VTOPVs. Ideally, a transparent conductor shall have both high transparency and low resistance for effective charge collection. Some recently developed conductive materials, such as carbon nanotubes, graphene, poly(3,4-ethylenedioxy-thiophene): poly(styrene sulfonate) (PEDOT:PSS), and silver nanowires (Ag-NWs), may meet the requirement for the transparent conductors. If the photoactive materials exhibit considerably high efficiency with the photons collected in UV and NIR regions, and match with one of the conductor materials described above, the resultant OPVs may be good candidates for a transparent solar window module. Chun-Chao Chen et. al recently reported a photoactive layer of a BHJ blend consisting of the NIR light-sensitive PV polymer poly(2,6′-4,8-bis(5-ethylhexylthienyl)benzo-[1,2-b;3,4-b]dithiophene-alt-5-dibutyloctyl-3,6-bis(5-bromothiophen-2-yl)pyrrolo[3,4-c]pyrrole-1,4-dione) (PBDTT-DPP) as the electron donor and PCBM as the electron acceptor in an article titled Visibly Transparent Polymer Solar Cells Produced by Solution Processing (ACS Nano 2012, 6(8), pp 7185-7190). The resultant OPVs gave rise to about 4% PCE with an average light transmission of 61% over the 400 to 650 nm, which made the solar glass almost fully transparent.

Although VTOPVs may achieve almost full transparency, their main drawbacks are low efficiency. If the semitransparent perovskite solar cells are introduced to hybrid with the transparent VTOPVs, high efficiency of the perovskite solar cells may compensate the polymer ones. With organic-inorganic halide photoactive materials, the perovskite solar cells possess similar structure to the OPVs. In addition, they can be both prepared with low temperatures and solution processes. For example, transparent flexible conductive plastic substrates such as Sn-doped indium oxide/polyethylene naphthalate (ITO/PEN) and Sn-doped indium oxide/polyethylene terephthalate (ITO/PET) have been utilized as substrates to fabricate plastic based flexible photovoltaic devices. The same substrates have also been used as the substrates of OPVs. Both of the perovskite and the polymer solar cells can be fabricated below 150° C. without affecting physical properties of the plastic substrates. Therefore, they can be fabricated together on a single substrate with the same process. If one half of a flexible substrate is covered with a group of the VTOPVs possessing 4% of PCE and the other half is deposited with a group of the semitransparent perovskite solar cells showing 10% of PCE, for example, the average PCE of the entire flexible solar module may reach to 7.5%.

From the perspective of appearance, aesthetics and practical application, such an idea described above is excellent and practical. In general, the glass windows of family houses and apartments are not coated. The sunlight penetrating the windows in summer significantly increases energy bills for the house owners. Although curtains or blinds can partially block the sunlight and save the energy costs consumed in air conditioning, they make the indoor space dark. Therefore, some families tend to buy colorful window films adhered onto the glass windows to reduce the heat from the sunlight and decorate their houses or apartments. However, these window films do not generate any energy. The present invention can provide colorless or colorful window films that not only reduce the heat transmission but also generate energy. These solar window membrane modules can also be used to commercial buildings including skyscrapers. Because they are easily installed and replaced, the solar window membrane modules are economical products for both of appearance decoration and energy generation of the commercial buildings.

The main difficulty to change the windows of a building into a component of BIPV is not only the transparency, but also the service life of the solar window membrane modules. A building is built for a century lifetime, but the most reliable silicon crystal solar modules can only be used for about twenty years. It may be a good way to solve this problem by utilizing a replaceable transparent or semitransparent solar window membrane module that can be easily adhered onto a window glass. If this solar window membrane module is inexpensive, easy to prepare and replace, it can be simply replaced with a new one anytime when it is decayed.

The present invention provides a flexible transparent-semitransparent hybrid solar window membrane module. This module looks like a thin membrane, transparent, semi-transparent, or hybrid, to be adhered onto the glass windows of a building, indoors or outdoors. The membrane module may be visibly transparent and comprised with a series of VTOPVs, semitransparent and comprised with a series of perovskite solar cells, or hybrid with both types of them. Every solar window membrane module may contain one or more PV junction boxes that may be interconnected with neighbor modules, wired or wireless. A wireless solar window membrane module may be mainly adhered onto external surface of a glass window. A wireless junction box contains a piece of wireless discharge module that transfers energy through the air to a piece of charge device. The thin film solar window module can be easily adhered onto the glass surfaces through electrostatic adsorption. As a result, the solar window membrane module in the present invention can be simply installed and replaced. Both types of solar cells can be easily prepared via roll-to-roll solution processes with inexpensive costs. If they are installed to cover most glass windows of a building, they may provide most energy necessary to the whole building.

### SUMMARY OF THE INVENTION

The present invention provides a kind of flexible transparent-semitransparent hybrid membrane solar window modules. These solar window modules may be visibly transparent and comprised of a series of thin film VTOPVs, semitransparent and comprised of a series of perovskite solar cells, or hybrid of both types of solar cells. Those VTOPVs contain a UV- and/or NIR-sensitive polymer layer so that most visible light located between wavelengths of 450 nm and 650 nm can transmit through the solar cells deposited on transparent substrates. Although a perovskite solar cell absorbs the visible light, the photoactive materials can be modified or its thickness may be reduced to allow some visible light transmit its absorber layer, which can result in semi-transparent solar cells. Due to their intrinsic high efficiency, such modifications could still give rise to semi-transparent perovskite solar cells with over 10% of PCE. Taking into account the transparency, efficiency and aesthetics, one can apply combinations of the perovskite solar cells and the VTOPVs to the windows of buildings as power sources. The solar cells are deposited onto a flexible thin transparent plastic membrane such as polyethylene terephthalate (PET) or polyethylene naphthalate (PEN). With silicon coating on its surface contacting to the window glass, the resultant module can be adhered onto the indoor or outdoor surface of a glass window via electrostatic adsorption and easily removed or replaced. If it is adhered onto the external surface of a glass window, its interconnection with other modules may be carried out wirelessly through resonant inductive coupling technology.

The structure for a perovskite solar cell in the present invention may be comprised of the different layers including a conducting polymer such as PEDOT:PSS, a perovskite, and a PCBM or C₆₀. The structure of a VTOPV may be comprised of a conducting polymer such as PEDOT:PSS layer, a photoactive layer containing low band-gap NIR and/or UV sensitive organic polymer, and a layer of PCBM or PC₇₁BM. Because these two kinds of solar cells possess considerably similar structure and fabrication conditions, a flexible transparent-semitransparent hybrid solar window module can be manufactured through a roll-to-roll production line with similar methods and art of fabrication.

Every solar window membrane module includes a series of VTOPVs and/or perovskite solar cells. These VTOPVs and perovskite solar cells have to be interconnected together, respectively, according to output requirements. Two methods are applied to the cell interconnection. One is to use metallic strips adhered onto the bus bars of the cells. The other is to apply three scribing steps (3P) during the deposition process of a solar cell. Finally, the modules have to be encapsulated to increase their lifetimes. The materials used for the encapsulation should be transparent, UV stable and inexpensive. The manufacture processes involved in the present invention are non-vacuum solution depositions, such as printing and spray methods. The processes will be revealed in another dividend invention.

### BRIEF DESCRIPTION OF THE DRAWINGS

FIG. 1 shows architectures of some flexible transparent-semitransparent hybrid solar window membrane modules.

FIG. 2 illustrates the structures of a semitransparent perovskite solar cell and a VTOPV printed on the same flexible membrane substrate.

FIG. 3 demonstrates interconnection of the transparent or semitransparent solar cells using conductive strips on a flexible solar window membrane module.

FIG. 4 demonstrates interconnection of the transparent or semitransparent solar cells through 3P scribing processes on a flexible solar window membrane module.

### DETAILED DESCRIPTION OF THE INVENTION

Architectures of the Flexible Transparent-Semitransparent Hybrid Solar Window Membrane Modules

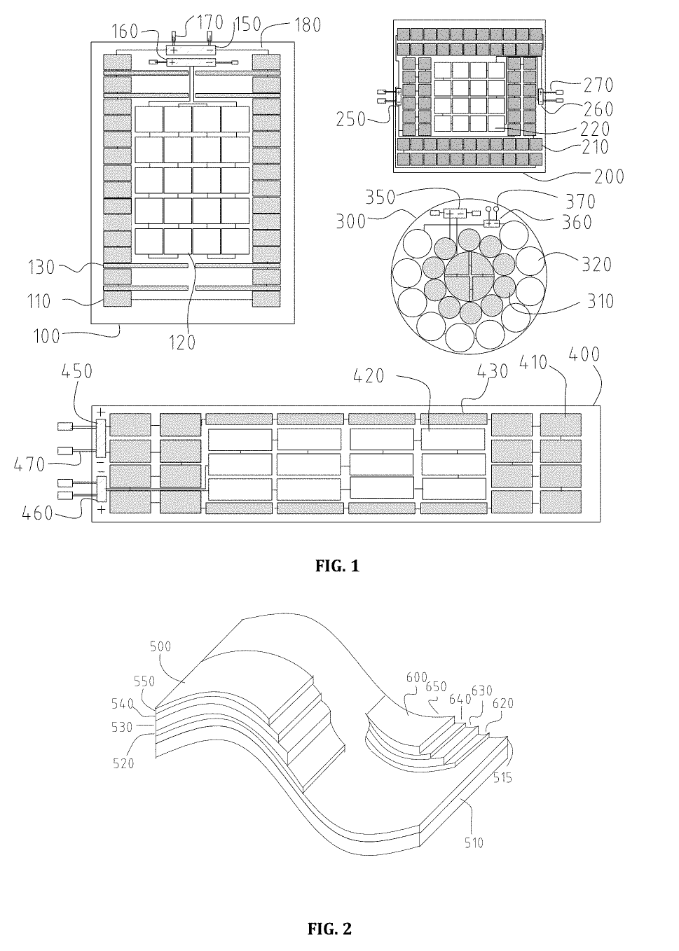

The present invention provides flexible transparent-semitransparent hybrid solar window membrane modules that are comprised of a number of interconnected semitransparent organic-inorganic halide perovskite solar cells, VTOPVs, or both semitransparent and transparent ones on the same modules. FIG. 1 illustrates four examples of these transparent-semitransparent hybrid solar modules. As shown in module 100, the gray rectangles 110 represent semitransparent organic-inorganic halide perovskite solar cells. They may have different shapes like 130 but with the same areas and components. The colors of these perovskite solar cells can be selected by adjusting compositions and thicknesses of the perovskite active materials. Because some amount of visible light can still transmit the perovskite layers, the cells look semitransparent. The areas of these semitransparent solar cells are predesigned to meet the requirements of the output voltage and current for each module. All of the semitransparent solar cells 110 and 130 in the module 100 are interconnected in series (or in parallel if necessary) via the electrically conductive wires or strips 180, or in another way, through 3P scribing processes. The positive and the negative terminals of the resultant solar cell series are connected to the positive and the negative contacts in a junction box 150 that shows two polar output terminals 170. Said junction box 150 can be made very thin, i.e., <5 mm in thickness. If a module is adhered onto the external surface of a window glass, the terminals 170 may not be necessary because a wireless discharging device such as a resonant inductive coupling module may be installed inside said junction box to electrically communicate with adjacent modules. Similarly to the perovskite solar cells, the rectangles 120 stand for VTOPVs. They may have different contours, but all of the interconnected cells should have the same areas and compositions. All of these transparent solar cells are interconnected in series (or in parallel if necessary) with the electrically conductive wires or strips 180, or through the 3P scribing processes, and the cell series is connected to the other junction box 160.

As shown in FIG. 1, another module 200 possesses a square shape. Similar to the module 100, the semitransparent perovskite solar cells 210 are interconnected in series and connected to a junction box 250. Similarly, the VTOPVs 220 are interconnected in series as well and connected to the other junction box 260. Both of the junction boxes in the module 200 have polar output contact terminals 270. If the modules are adhered onto the external surfaces of the windows, in some cases, the junction boxes may not have these output contact terminals because the electricity flowing out of the junction boxes may be wirelessly connected to other adjacent modules through resonant inductive coupling technology.

Module 300 fits to an abnormal window shape. All of the solar cells are fabricated with round shapes in this case. When the spray or printing methods are used to fabricate these solar modules, any shapes of the solar cells can be achieved with software. The semitransparent perovskite solar cells 310 possess different contours but the same areas and compositions. The interconnected cell series are connected to a junction box 350. Similarly, the other group of VTOPVs 320 is connected to the other junction box 360. For two groups of said solar cells in the same module, it should be reminded that the electrically conductive wires of strips must be insulated well for each group to avoid mutual disturbance between two groups of the solar cells. The polar output terminals 370 of two junction boxes may be unnecessary if the electricity is delivered wirelessly through the resonant inductive coupling method.

Another module 400 shows the semitransparent perovskite solar cells 410 and 430 that possess the same areas and components but different contours. In the present embodiment, all of the perovskite solar cells are interconnected in series and connected into a junction box 450. Similarly, the VTOPVs 420 are interconnected in series as well and connected into another junction box 460. Although two junction boxes have the polar terminals 470, they may be ignored in the cases of wireless electricity transfer. The window styles where the modules 400 can be used are frequently seen in a skyscraper or a family house. In particular, some buildings may welcome colorful decorations.

For all of different modules illustrated in FIG. 1, two or more modules can be interconnected via their junction boxes to form a solar array. A number of arrays can be interconnected in series or in parallel to form a power station in combination with other solar power sources. If these flexible solar window membrane modules are used in a family house, they may be adhered onto internal surfaces of the glass windows because there are usually no coatings on these glass windows. The uncoated window glass allows most light transmitted to work on the indoor modules. Under this circumstance, the common cables are suitable for the interconnection among different modules. If a user worries that the double layer window glass may still block some sunlight so as to reduce the PCEs of the modules, he/she may consider use outdoor modules. If the present solar modules are applied onto the glass windows of a skyscraper, they may have to be adhered onto the external surfaces of the windows since the window glass is normally coated to reduce the sunlight and heat into the building. Under this circumstance, the cables used to interconnect different modules should be carefully selected as small and hidden as possible to avoid any uncomfortable views.

For the flexible solar window modules used on the outdoor windows, wireless interconnection may be applied to interconnect the different modules. There are different technologies today for wireless power technologies, such as inductive coupling, resonant inductive coupling, capacitive coupling, magneto-dynamic coupling, microwaves, and light waves. In consideration of the power transmittance distance and costs, the method of resonant inductive coupling that can transmit a great power to some distance may be suitable for the present application. A power transmitter can be incorporated into the junction boxes of a module, which can provide power to a receiver nearby the junction boxes. The resonant inductive coupling is a form of inductive coupling in which power is transferred by magnetic field between two resonant circuits, one in the transmitter and the other one in the receiver. Each resonant circuit consists of a coil of wire and both of them are tuned to resonate at the same resonant frequency. The resonant inductive coupling can achieve high efficiency at ranges of 4 to 10 times the coil diameter, which suggests that 2 cm diameter coil can transfer the power to a distance between 8-20 cm. Therefore, several modules can be arranged to let their junction boxes close to a single receiver. This group of the solar modules becomes a small solar array. With development of the wireless power technologies, the transmitter circuit and the receiver device should become tiny and cheap enough to be incorporated into the flexible solar window modules. These receiver devices can be wired into the building and interconnected one another to generate more power. Because the wireless power transmittance depends on the frequency and the data control, every individual transmitter should deliver the electricity to the common receiver device without mutual interference.

Structures of the Perovskite Solar Cells and the VTOPVs.

FIG. 2 demonstrates the layer-by-layer structures of an organic-inorganic halide perovskite solar cell and a VTOPV on the same polymer substrate. The substrate used in the present invention should be flexible and transparent. The best candidates may be some polyester films, such as PET and PEN. They have been extensively investigated and applied as flexible substrates of OPVs. Their melting points and glass transition temperatures are 255° C. and 78° C. for PET, and 263° C. and 120° C. for PEN, respectively. In addition, they are both transparent with the total light transmission larger than 85% over the range of 400-800 nm with a haze of less than 0.7%, according to some referenced data (MacDonald, W. A. and Mace, J. M., Flexible Substrate Requirements for Organic Photovoltaics. Organic Photovoltaics, Brabec, C., Scherf, U. and Dyakonov (Eds), 2^{nd} Edition, 2011, P. 513-530). More candidates for the flexible thin film substrates may include polysulfone resin (PSU), polyvinylidene difluoride (PVDF), poly(tetrafluoroethylene) (PTFE), polycarbonate (PC), polyethersulfone (PES), polyethylenimine (PEI), or polyether ether ketone (PEEK).

As shown in FIG. 2, a layer 515 of transparent conductive oxide (TCO), mostly indium tin oxide (ITO), has been coated on the surfaces of the polymer substrate 510. More materials of TCO may include Al doped ZnO (AZO), indium doped ZnO (IZO), and/or fluorine doped tin oxide (FTO). The thickness of this polyester substrate such as PET or PEN may be 10-300 micrometer (μm), preferably 50-150 μm. The thickness of the ITO layer may be 50-200 nm. Such a conducting polymer membrane is commercially available. The layer of ITO can also be deposited with sputtering or other methods. There are several layers for the perovskite solar cell 500. The first coating 520 deposited onto the ITO surface is probably a highly conductive material, such as PEDOT:PSS, with a thickness ranging from 30 to 200 nm. This layer may not be necessary since the ITO layer on the substrate has already plays a role of the conductive anode. However, a thin PEDOT:PSS layer is used here as a hole transport layer (HTL) for selective flow of holes to the anode 520. It also affects the planarization of the underlying ITO electrode and improves the interface quality between the anode and the active layer. Due to its high optical transparency in the visible region, high work function and easy to solution processes, therefore, it has been extensively used in OPVs. It is a commercially available chemical but requires some skills to obtain a smooth and compact coating. The conducting polymer PEDOT:PSS may be replaced by some other metal oxides such as TiO₂, NiOₓ, MoO₃, V₂O₅, and/or WO₃ in some applications to obtain better qualities of the main layers. However, the main photoactive perovskite layer 530 is usually deposited onto the surface of the PEDOT:PSS layer 520 in the present invention.

The materials of the perovskite solar cells in the present invention are organic-inorganic halide CH₃NH₃BX₃ (B=Sn, Pb; X=Cl, Br, I). The thicknesses of these perovskite materials are between 50 and 300 nm. Here said perovskite materials may be CH₃NH₃PbI₃, CH₃NH₃PbBr₃, CH₃NH₃PbCl₃, CH₃NH₃SnI₃, CH₃NH₃SnBr₃, CH₃NH₃SnCl₃, PH₃NH₃PbI₃₋ₓClₓ, PH₃NH₃PbBr₃₋ₓClₓ, PH₃NH₃SnI₃₋ₓClₓ, PH₃NH₃SnBr₃₋ₓClₓ, CH₃CH₂NH₃PbI₃, CH₃CH₂NH₃PbBr₃, CH₃CH₂NH₃PbCl₃, CH₃CH₂NH₃SnI₃, CH₃CH₂NH₃SnBr₃, CH₃CH₂NH₃SnCl₃, CH₃CH₂NH₃SnI₃, CH₃CH₂NH₃SnBr₃, and/or CH₃CH₂NH₃SnCl₃.

Above this perovskite layer 530, is deposited with a layer of PCBM, PC₇₁BM, or C₆₀ as an electron transport layer (ETL) 540. The configuration of HTL-perovskite-ETL gives rise to an inverted planar p-i-n structure of the perovskite solar cell. The p-i-n inverted planar structure of perovskite solar cells showed the advantages of high efficiencies, low temperature processing and flexibility. The thickness for this ETL layer applied in the present invention is between 20 and 300 nm. On the top of this p-i-n structure, Ag or Al finger lines and bus bars may be directly deposited via a screen print method as a conductive cathode 550. In some cases, a cathode layer 550 may only be some TCO material. For example, ITO possesses a work function (WF) between 4.1 and 4.7 eV, covering a range from Al (4.06-4.26 eV) to Ag (4.26-4.74 eV). Therefore, it can be utilized to replace the top metallic grid as a cathode. The other TCO materials for this layer 550 may be highly conductive AZO, IZO, or FTO. If a TCO layer is used as a top electrode, for this inverted structure, a thin layer (10-50 nm) of ZnO has to be inserted between the ETL layer 540 and the TCO layer 550 to compensate difference of their energy levels. In order to increase the conductivity of the top TCO layer 550, we can consider to dope silver nanowire (Ag-NW) into this TCO layer if necessary. With this TCO cathode, interconnection of neighboring cells is conducted through 3P scribing processes during deposition of the solar cells. On the other hand, the cells with the metallic grids possessing thicknesses of 50-150 nm have to be interconnected one another with some electrically conductive wires or strips.

In addition to the inverted structure, a conventional n-i-p structure of the perovikite solar cell may also be used. Its stacked structure is arranged as TCO/ZnO/ETL/perovskite/HTL/TCO with the 3P scribing interconnection of neighboring cells, or TCO/ZnO/ETL/perovskite/HTL/Ag or Au grid with electrically conductive strips wired interconnection of neighboring cells.

The layer structure of a VTOPV 600 is also illustrated in FIG. 2. This VTOPV may have both conventional and inverted planar structures. Similar to the perovskite solar cell 500, the HTL layer of a conventional structure above the TCO layer 515 is commonly a PEDOT:PSS layer 620 with a thickness of 30-200 nm. In some applications, the layer 620 may be replaced with some other HTL materials such as TiO₂, NiOₓ, MoO₃, V₂O₅, WO₃, etc. The NIR and UV sensitive photoactive layer 630 is deposited onto the layer of PEDOT:PSS with a thickness of 50-300 nm, wherein the materials of said photoactive layers may be PBDTT-SeDPP, PBDTT-DPP, poly[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl] (PTB7), poly[2,5-bis(3-dodecylthiophen-2-yl)thieno[3,2-b]thiophene] (pBTTT), poly(3-hethylthiophene) (P3HT), etc. In this conventional VTOPV 600, the photoactive layer 630 plays a donor role. Above this layer 630, an acceptor ETL layer 640 of PC₇₁BM, PCBM, or C₆₀ is deposited with a thickness of 20-300 nm. The layers of 630 and 640 give rise to a BHJ device. Although the conjugated polymers are extensively selectable as the donor materials, the acceptor materials are narrowly limited to some fullerene derivatives, especially PCBM and PC₇₁BM. On the top of this BHJ structure, a cathode layer 650 may be TCO with a thickness between 50 and 200 nm. The materials for this layer 650 may also be TiO₂ covered with Ag-NW composite TCO as a transparent cathode, or thin ZnO (10-50 nm) covered with ITO, AZO, IZO or FTO. With this TCO cathode, interconnection of neighboring cells is conducted through 3P scribing processes during deposition of the solar cells. On the other hand, the top TCO cathode may be replaced with an Al or Au grid of finger lines and bus bars, screen-printed to a thickness of 50-150 nm.

In an inverted configuration, the stacked structure is TCO/ZnO/ETL/photoactive layer/HTL/TCO or TCO/ZnO/ETL/photoactive layer/HTL/Ag or Au grid. The cathode layer 515 has to be deposited with a thin ZnO layer (10-50 nm), followed with a ETL layer 620 of PCBM, PC₇₁BM or C₆₀ as acceptor and NIR/UV photoactive layer 630 as donor to form a BHJ structure. The HTL layer 640 may be PEDOT:PSS, TiO₂, NiOₓ, MoO₃, V₂O₅, or WO₃ covered with a metallic grid 650 of Ag or Au finger lines and bus bars as a conductive anode. This metallic grid may be screen printed to a thickness of 50-150 nm. In another exemplary embodiment, the metallic grid may be replaced with a TCO layer, i.e., ITO, AZO, IZO or FTO, probably composed with Ag-NW on the cell top as a transparent anode. In the present invention, we prefer to use the inverted architecture. This configuration allows one to use high work function metals like Ag or Au instead of low work function metals like Al on top of the device as the anode to increase the stability of the solar window modules.

The most popular materials for the layer 630 are conjugated polymers, such as polythiophenes, polyfluorenes or polycarbazoles. In the present invention, the low bandgap organic semiconductors with major absorption in NIR and UV regions are preferred to fabricate VTOPVs. For example, since the optical bandgaps are narrow for the NIR sensitive materials, the open circuit voltages (V_{OC}) of them are small. Therefore, we prefer to fabricate the solar cells with small sizes and allow more cells interconnect one another to increase the output voltages of the modules. For those materials with the main absorption in the UV region, almost all of the visible light will transmit the absorb layer. The resultant modules may be highly transparent. Because of wide optical bandgaps, the V_{OC} of these materials are large. As a result, we may design their cells with large areas to increase their short circuit currents (i_{SC}).

The real products may comprise different layer structures or various configurations. The inverted structure is preferable for both perovskite solar cells and VTOPVs in the present invention. Since we use the solution processing methods to fabricate the solar modules, we can use the different solutions to print or spray different materials, and even increase or decrease numbers of the layers. If it is necessary, we can increase or decrease the modular sections of a solution processing equipment to meet the fabrication conditions in a roll-to-roll production line.

Interconnections of the Cells and Encapsulation of the Solar Modules

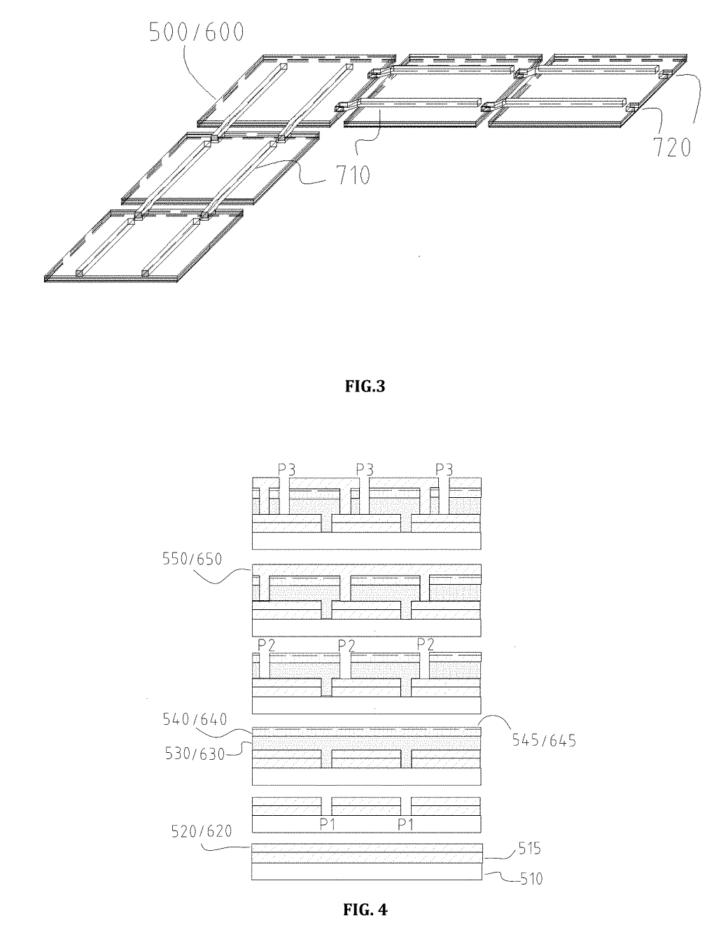

All of the semitransparent perovskite solar cells in a flexible solar window membrane module have to be connected in series together. The common positive and negative terminals shall be connected to the positive and the negative contacts inside a junction box 450. In the same way, all of the VTOPVs shall be interconnected and further connected to the junction box 460. There are two ways for these interconnections of the solar cells on the modules. One is to use the electrically conductive wires or strips, wherein the materials of said conductive wires or strips include Cu, Ni, Al, Ag, or carbon nanotube (CNT). In this way, the substrates used as naked without ITO layer that can be printed or sprayed later to form isolated cells in the production line. If the substrate used is coated with ITO, the ITO layer has to be scribed according to the predesigned cell areas. After completions of the layers ITO 515, or ITO 515 plus an HTL layer 520 or 620 such as PEDOT:PSS, leave some contact areas 720 not to be covered with the other layers on the surface edges of the bottom conductive anode or cathode layers, and then print the following layers. As shown in FIG. 3, five semitransparent perovskite cells 500 or VTOPVs 600 are interconnected in series around a corner. The electrically conductive wires or strips 710 are adhered to the bus bars of the metallic grid printed on the top of a cell, and connected to the bottom conductive layer of a neighboring cell via the cuts 720 that are not deposited with the photoactive layers and the other layers on their tops. The adhesive used to adhere said electrically conductive wires or strips is usually conductive Ag paste that can be cured at a low temperature below 150° C. The metallic bus bars and the figure lines (not shown in FIG. 3) can be screen printed on the surfaces of the solar cells.

The other preferred electrical interconnects between adjacent cells is demonstrated in FIG. 4. This method does not introduce metallic strips, but scribe three individual lines (P1, P2 and P3) during manufacturing processes. As illustrated with FIG. 4, the layer deposition orders and the three scribing steps are displayed from the bottom to the top. At the beginning, a scribing process P1 utilizing pulsed laser sources with femtosecond to nanosecond pulse durations at different wavelengths is applied to the bottom conductive layers consisting of ITO 515, or ITO 515 plus PEDOT:PSS 520 or 620 (an HTL layer), to isolate different cells. If the layer 520 or 620 represents an ETL layer, it shall be deposited after the P1 scribing step, following the deposition of a thin ZnO layer. The Photoactive absorber layers 530 or 630 and the buffer layers 540 or 640, plus a possible thin ZnO layer 545 or 645 if the layers 540 or 640 are the ETL ones, are deposited after the P1 scribing process, followed by a P2 scribing process to expose the bottom conductive layers of neighboring cells. The top TCO layers 550 or 650 are eventually deposited, which achieves the interconnections between the top electrically conductive TCO layer of a cell and the bottom electrically conductive layer of a neighboring cell. The P3 scribing processes are finally applied to isolate the different cells. Although the P2 and the P3 scribing processes are often carried out using mechanical needle scribes, the pulse laser scribing similar to the P1 processes are preferred in the present invention because the scribing processes may be more reliable with the flexible thin film substrates during a roll-to-roll manufacture process. In a roll-to-roll process, the substrate roll delivery speed is required at least 1-2 meters/minute. The high energy and ultra-short laser pulse scribing processes will meet the industrial manufacture requirement. The state-of-the-art laser pulse technology can remain high quality of the scribing on a flexible polymer substrate without damaging it.

The present flexible solar window membrane modules are most likely used outdoors. They have to be encapsulated to prevent from attacks of oxygen and moisture, which prevents from extrinsic degradation and significantly increases the lifetimes of the solar modules. The present invention prefers to obtain water vapor transmission rate (WVTR) and oxygen transmission rate (OTR) within the ranges of 10⁻³-10⁻⁶ g/m²/day and 10⁻³-10⁻⁵ cm³/m²/day/atm, respectively. The materials for the encapsulation should allow at least 90% of incident light transmitted without UV absorption degradation. The encapsulation methods may be carried out with a roll lamination system encapsulating the perovskite solar cells and VTOPVs between two sheets uniting them with an adhesive, followed by a possible heating sealing, a process which basically consists of supplying thermal energy on outside of package to soften/melt the sealants. The encapsulation process can also be conducted with an automatic laminator under conditions of heating and vacuuming.

The materials for the encapsulation include a front sheet and a back sheet barrier foils. Both of them can be PET or PEN with a thickness between 10-100 μm. They are flexible, transparent and able to significantly block penetration of moisture and oxygen. Other candidates for the front and back sheet barrier foils may include PSU, PVDF, PTFE, PC, PES, PEI, or PEEK. For the back sheet barrier foils, the external surfaces shall be coated with a silicon layer for electrostatic adsorption onto the glass surfaces.

Besides the barrier foils, the most important encapsulation material is adhesive with crosslinking network to seal the solar cells. The commercial adhesives for the flexible solar module encapsulation may be liquids or solids. The typical solid adhesive film is ethylene vinyl acetate (EVA) film that is usually used inside a laminator with heating and vacuuming. Because EVA film is not resistant to UV adsorption degradation and blocks the UV light below 380 nm, we prefer to use other adhesives, especially radiation curing liquid adhesives. An idea adhesive should be fully transparent, UV radiation initiated, resistant to moisture and oxygen permeation, and quickly cured to meet requirement of a roll-to-roll manufacture line. Basic components for one group of these adhesives, for example, may be acrylic adhesives, including base acrylic ester resins such as acrylic acid, reactive diluents, and flexibilizers/cross-linkers of polyester, polyether, or urethane acrylate type. These components of the adhesives can achieve very transparent systems if mono- or bisacylphosphineoxides are used as initiators. In addition, the transparency may remain over the lifetimes of the solar modules if some UV blockers/UV stabilizers, such as triphenylphosphineoxide (TPPO) and 2-(2H-benzotriazol-2-yl)-4,6-ditertpentylphenol, are further used with the adhesives.

Another important group of radiation curing barrier adhesives is an epoxy system cured by a cationic mechanism. Basic components of these adhesives may include 7-oxabicyclo[4.1.0]hept-3-ylmethyl, 7-oxabicyclo[4.1.0]heptane-3-carboxylate, bis(7-oxabicyclo[4.1.0]hept-3-ylmethyl) hexanedioate, and diglycidylether of bisphenol-A. This group of adhesives may result in better resistance to water and oxygen permeation, less stress on the flexible active layers and substrates, but less flexibility than the acrylic group mentioned above, due to their high cross-linking density. The information of these two groups of the adhesives were described in reference (Rojahn, M., Schmidt, M., and Kreul, K., Adhesives for Organic Photovoltaic Packaging. Organic Photovoltaics, Brabec, C., Scherf, U. and Dyakonov (Eds), 2^{nd} Edition, 2011, P. 539-559). Besides, some commercial adhesives such as NOA series are available.

In conclusion, the flexible solar window membrane modules provided in the present invention possess many advantages, such as transparency, considerably high power conversion efficiencies, simple and inexpensive preparation, easy use, and replaceability. Therefore, they can be extensively used as power devices of BIPV.

What is claimed is:

1. A flexible transparent-semitransparent hybrid solar window membrane module comprising:
one or more semitransparent perovskite solar cells deposited onto a thin film substrate;
one or more visibly transparent organic polymer solar cells (VTOPVs) deposited onto said thin film substrate; and
one or two junction boxes installed on said thin film substrate, wherein said junction boxes may include two output terminals or one built-in wireless discharging module;
wherein said thin film substrates are transparent polymers of polyethylene terephthalate (PET), polyethylene naphthalate (PEN), polysulfone resin (PSU), polyvinylidene difluoride (PVDF), poly(tetrafluoroethylene) (PTFE), polycarbonate (PC), polyethersulfone (PES), polyethylenimine (PEI), or polyether ether ketone (PEEK), with a thickness of 10-300 μm.

2. The perovskite solar cells of claim 1 including:
one or more transparent conductive oxide (TCO) layers with a thickness of 50-200 nm, wherein the materials of said TCO layers are indium-tin-oxide (ITO), Al doped ZnO (AZO), indium doped ZnO (IZO), and/or fluorine doped tin oxide (FTO);
one or more hole transport layers (HTL) with a thickness of 30-200 nm, wherein the materials of said HTL layers are poly(3,4-ethylenedioxythiophene):poly(styrene sulfonate) (PEDOT:PSS), TiO₂, NiOₓ, MoO₃, V₂O₅, and/or WO₃;
one or more perovskite photoactive layers with a thickness of 50-300 nm, wherein said perovskite materials are CH₃NH₃PbI₃, CH₃NH₃PbBr₃, CH₃NH₃PbCl₃, CH₃NH₃SnI₃, CH₃NH₃SnBr₃, CH₃NH₃SnCl₃, PH₃NH₃PbI₃₋ₓClₓ, PH₃NH₃PbBr₃₋ₓClₓ, PH₃NH₃SnI₃₋ₓClₓ, PH₃NH₃SnBr₃₋ₓClₓ, CH₃CH₂NH₃PbI₃, CH₃CH₂NH₃PbBr₃, CH₃CH₂NH₃PbCl₃, CH₃CH₂NH₃SnI₃, CH₃CH₂NH₃SnBr₃, CH₃CH₂NH₃SnCl₃, CH₃CH₂NH₃SnI₃, CH₃CH₂NH₃SnBr₃, and/or CH₃CH₂NH₃SnCl₃;
one or more electron transport layers (ETL) with a thickness of 20-300 nm, wherein the materials of said ETL layers are [6,6]-phenyl C₆₁ butyric acid methyl ester (PCBM), [6,6]-phenyl C₇₁ butyric acid methyl ester (PC₇₁BM), and/or C₆₀;
one ZnO layer with a thickness of 10-50 nm;
one or more TCO layers with a thickness of 50-200 nm, wherein the materials of said TCO layers are ITO, AZO, IZO, and/or FTO; and/or
one metallic grid comprising one or more bus bars and finger lines, wherein said metallic grid possesses a thickness of 50-150 nm and is made of Ag, Al, or Au;
wherein said different layers may be stacked from the bottom to the top of said perovskite solar cells according to a conventional n-i-p planar structure as TCO/ZnO/ETL/perovskite/HTL/TCO or TCO/ZnO/ETL/perovskite/HTL/Ag or Au grid, or an inverted p-i-n structure as TCO/HTL/perovskite/ETL/ZnO/TCO or TCO/HTL/perovskite/ETL/Al or Ag grid, and said inverted structure is preferable.

3. The VTOPVs of claim 1 including:
one or more transparent conductive oxide (TCO) layers with a thickness of 50-200 nm, wherein the materials of said TCO layers are ITO, AZO, IZO, and/or FTO;
one or more HTL layer with a thickness of 30-200 nm, wherein the materials of said HTL layer are PEDOT:PSS, TiO₂, NiOₓ, MoO₃, V₂O₅, and/or WO₃;
one or more ultraviolet (UV) and/or near infrared (NIR) sensitive photoactive layers with a thickness of 50-300 nm, wherein the materials of said photoactive layers are poly-{2,6′-4,8-di(5-ethylhexylthienyl)benzo[1,2-b;3,4-b]dithiophene-alt-2,5-bis(2-butyloctyl)-3,6-bis(selenophene-2-yl)pyrrolo[3,4-c]pyrrole-1,4-dione} (PBDTT-SeDPP), poly(2,6′-4,8-bis(5-ethylhexylthienyl)benzo-[1,2-b;3,4-b]dithiophene-alt-5-dibutyloctyl-3,6-bis(5-bromothiophen-2-yl)pyrrolo[3,4-c]pyrrole-1,4-dione) (PBDTT-DPP), poly[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl] (PTB7), poly[2,5-bis(3-dodecylthiophen-2-yl)thieno [3,2-b]thiophene] (pBTTT), and/or poly(3-hethylthiophene) (P3HT);
one or more ETL layers with a thickness of 20-300 nm, wherein the materials of said ETL layers are PC₇₁BM, PCBM, and/or C₆₀;
one ZnO layer with a thickness of 10-50 nm;
one or more TCO layers with a thickness of 50-200 nm, wherein the materials of said TCO layers are ITO, AZO, IZO, and/or FTO; and/or
one metallic grid comprising one or more bus bars and finger lines, wherein said metallic grid possesses a thickness of 50-150 nm and is made of Ag, Al, or Au;
wherein the above said layers are stacked in order from the bottom to the top as a conventional structure: TCO/HTL/photoactive layer/ETL/ZnO/TCO or TCO/HTL/photoactive layer/ETL/Al grid, or as an inverted structure: TCO/ZnO/ETL/photoactive layer/HTL/TCO or TCO/ZnO/ETL/photoactive layer/HTL/Ag or Au grid, and said inverted structure is preferable.

4. In the module of claim 1, all of the perovskite solar cells and VTOPVs are respectively interconnected through three step scribing processes (3P) as following:
the first step (P1) to isolate said cells by scribing the deposited bottom TCO or TCO plus HTL layers down to the substrate film according to the predesigned solar cell areas;
the second step (P2) to scribe the deposited top ZnO, ETL, and/or perovskite or photoactive polymer layers down to the bottom HTL or TCO layer; and
the third step (P3) to isolate said cells by scribing the top TCO layer down to the bottom HTL or TCO layer;
wherein there is no metallic grid printed onto said top TCO layer.

5. In the module of claim 1, all of the perovskite solar cells and VTOPVs are respectively interconnected with electrically conductive wires or strips as following:
said electrically conductive wires or strips to be adhered onto the top bus bars of said solar cells with one end of each wire or strip extended beyond said cell edges;
the ends of said electrically conductive wires or strips beyond said cell edges to be adhered onto the cut areas close to the edges of neighboring said cells, wherein there is only the bottom TCO or TCO plus HTL layers deposited onto said substrate film;
wherein said metallic grid with bus bar and finger lines is printed onto said top TCO or HTL layer; and
wherein material of said electrically conductive wires or strips is Cu, Ni, Al, Ag, or carbon nanotube (CNT); and adhesives to adhere said electrically conductive wires or strips is low temperature cured conductive Ag paste.

6. The module of claim 1 is encapsulated, comprising:
one piece of transparent back sheet barrier film with a thickness of 10-100 μm;
one piece of transparent front sheet barrier film with a thickness of 10-100 μm,
wherein the materials for said back sheet and front sheet barrier films are PET, PEN, PSU, PVDF, PTFE, PC, PES, PEI, or PEEK; and
wherein said back sheet and front sheet barrier films to be united with adhesive materials to seal said solar window module, wherein said adhesive materials are transparent and quickly radiation cured;
wherein the external surface of said back sheet is coated with a silicon layer.
